(19) United States
(12) Patent Application Publication
(10) Pub. No.: US 2026/0144070 A1
(43) Pub. Date: May 21, 2026

(54) SEMICONDUCTOR PACKAGE INCLUDING GUARD STRUCTURE AND METHOD OF MANUFACTURING THE SAME

(71) Applicant: Samsung Electronics Co., Ltd., Suwon-si (KR)

(72) Inventors: Seunghwan BAEK, Suwon-si (KR); Byungkeun KANG, Suwon-si (KR); Younhwan SHIN, Suwon-si (KR); Dongju JANG, Suwon-si (KR); Hyeon HWANG, Suwon-si (KR)

(73) Assignee: Samsung Electronics Co., Ltd., Suwon-si (KR)

(21) Appl. No.: 19/361,244

(22) Filed: Oct. 17, 2025

(30) Foreign Application Priority Data
Nov. 19, 2024 (KR) 10-2024-0164995

(51) Int. Cl. H01L 23/00; H01L 21/56

(52) U.S. Cl. CPC H10W 42/121; H10W 74/01; H10W 74/15; H10W 90/724; H10W 90/734

(57) ABSTRACT

A semiconductor package includes a substrate having a lower surface and an upper surfaces facing the lower surface, the substrate including an insulating layer, and an interconnection layer on the insulating layer, a semiconductor chip electrically connected to the interconnection layer on the upper surface of the substrate and defining a chip region, a guard structure on at least one of the upper surface or the lower surface of the substrate and being horizontally outside the chip region, an encapsulant encapsulating at least a portion of the semiconductor chip on the upper surface of the substrate, and connection bumps on the lower surface of the substrate and electrically connected to the interconnection layer. The encapsulant includes a first filler having a spherical shape, and the guard structure includes a second filler having a polyhedral shape.

### CROSS-REFERENCE TO RELATED APPLICATION(S)

This application claims benefit of priority to Korean Patent Application No. 10-2024-0164995 filed on Nov. 19, 2024 in the Korean Intellectual Property Office, the disclosure of which is incorporated herein by reference in its entirety.

### BACKGROUND

The present disclosure relate to semiconductor packages and a methods of manufacturing the same.

As electronic devices have become lighter and have higher performance, the development of miniaturized and/or higher-performance semiconductor chips has been desired. In a cutting process of individualizing a plurality of semiconductor packages, if cutting is performed inside each package, semiconductor chips and connection bumps, etc. in the package may be damaged, which may cause problems in the reliability of the entire package.

### SUMMARY

Some example embodiments of the present inventive concepts provide semiconductor packages with improved reliability.

According to an example embodiment of the present inventive concepts, a semiconductor package includes a substrate having a lower surface and an upper surface facing the loser surface, the substrate including an insulating layer and an interconnection layer on the insulating layer, a semiconductor chip electrically connected to the interconnection layer on the upper surface of the substrate and defining a chip region, a guard structure on at least one of the upper surface or the lower surface of the substrate and being horizontally outside the chip region, an encapsulant encapsulating at least a portion of the semiconductor chip on the upper surface of the substrate, and connection bumps on the lower surface of the substrate and electrically connected to the interconnection layer, wherein the encapsulant includes a first filler having a spherical shape, and the guard structure includes a second filler having a polyhedral shape.

According to an example embodiment of the present inventive concepts, a semiconductor package includes a substrate including an insulating layer and an interconnection layer on the insulating layer, a semiconductor chip on the substrate and having conductive bumps electrically connected to the interconnection layer, an underfill portion encapsulating at least a portion of the conductive bumps below the semiconductor chip, guard structures around the semiconductor chip, an encapsulant encapsulating at least a portion of the semiconductor chip on the substrate, and connection bumps below the substrate and electrically connected to the interconnection layer, wherein the guard structures are arranged outside the connection bumps and are spaced apart from both an edge of the substrate and the underfill portion.

According to an example embodiment of the present inventive concepts, a method of manufacturing a semiconductor package includes providing a substrate including a plurality of unit regions and a dummy region surrounding an outer side of the plurality of unit regions, arranging semiconductor chips within the plurality of unit regions of the substrate, respectively, attaching guard structures arranged within at least one of the plurality of unit regions or the dummy region, forming an encapsulant covering each of the semiconductor chips and the guard structures within the plurality of unit regions of the substrate, and cutting the substrate and the encapsulant into a plurality of semiconductor packages using a saw blade, wherein the plurality of unit regions are divided by first scribe lanes extending in a first direction and second scribe lanes extending in a second direction, intersecting the first direction, and the guard structures are arranged adjacent to at least one side of each of the first scribe lanes and the second scribe lanes.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a cross-sectional view illustrating a semiconductor package according to an example embodiment of the present inventive concepts, and FIG. 1B is a plan view illustrating a cross-section taken along line I-I′ of FIG. 1A;

FIG. 2A is a cross-sectional view illustrating a semiconductor package according to an example embodiment of the present inventive concepts, and FIG. 2B is a bottom view of the semiconductor package of FIG. 2A;

FIG. 3A is a cross-sectional view illustrating a semiconductor package according to an example embodiment of the present inventive concepts, and FIG. 3B is a plan view illustrating a cross-section taken along line II-II′ of FIG. 3A;

FIGS. 4A to 4D are plan views schematically illustrating a process of manufacturing a semiconductor package according to an example embodiment of the present inventive concepts;

FIG. 5A is a partial enlarged view illustrating region ‘A’ of FIG. 4D, and FIG. 5B is a cross-sectional view illustrating a cross-section taken along line III-III′ of FIG. 5A; and

FIG. 6 is a plan view schematically illustrating an operation in the process of manufacturing a semiconductor package according to an example embodiment of the present inventive concepts.

### DETAILED DESCRIPTION

Hereinafter, some example embodiments of the present inventive concepts will be described with reference to the accompanying drawings. Unless otherwise specifically stated, in this specification, terms, such as ‘upper,’ ‘upper surface,’ ‘lower,’ ‘lower surface,’ and ‘side surface’ are based on the drawings and may actually vary depending on a direction in which the components are arranged.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

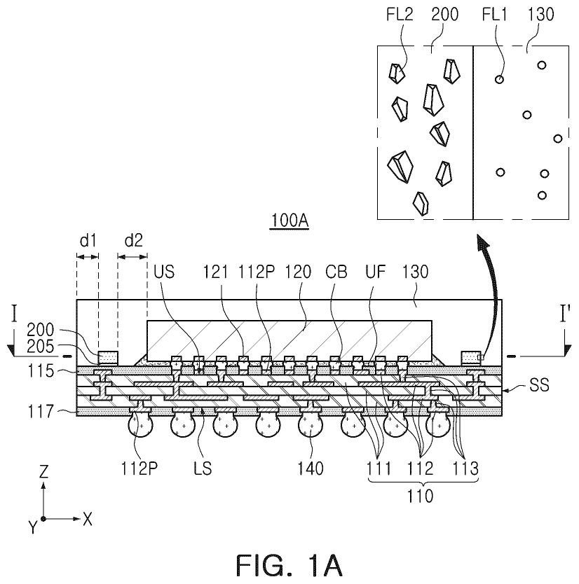

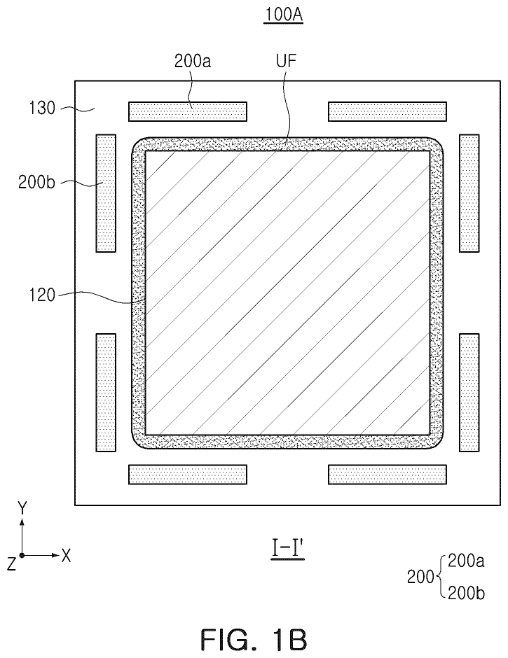

FIG. 1A is a cross-sectional view illustrating a semiconductor package 100A according to an example embodiment of the present inventive concepts, and FIG. 1B is a plan view illustrating a cross-section taken along line I-I′ of FIG. 1A.

Referring to FIGS. 1A and 1B, the semiconductor package 100A of an example embodiment may include a substrate 110, a semiconductor chip 120, a guard structure 200, and an encapsulant 130. Referring to FIGS. 1A and 1B, the semiconductor package 100A of an example embodiment may further include connection bumps 140.

The substrate 110 may be a support substrate on which the semiconductor chip 120 is mounted, and may be a package substrate for redistributing connection pads 121 of the semiconductor chip 120. The package substrate may include a printed circuit board (PCB), a ceramic substrate, a glass substrate, a tape interconnection board, etc. For example, the substrate 110 may have a lower surface LS and an upper surface US facing each other and may include an insulating layer 111, an interconnection layer 112, and an interconnection via 113.

The insulating layer 111 may include an insulating material. For example, the insulating material may include a thermosetting resin, such as an epoxy resin, a thermoplastic resin, such as polyimide, or a resin obtained by impregnating an inorganic filler or/and glass fiber (e.g., glass cloth or glass fabric) with the thermosetting resin or the thermoplastic resin, for example, prepreg, Ajinomoto buildup film (ABF), flame retardant (FR-4), bismaleimide triazine (BT), or photo-imageable dielectric (PID). For example, the insulating layer 111 may include a non-photosensitive resin, such as prepreg, ABF, or a photosensitive resin, such as PID.

The insulating layer 111 may include a plurality of insulating layers 111 stacked in a vertical direction (a Z-axis direction). The uppermost insulating layer 111 among the plurality of insulating layers 111 may provide an upper surface US of the substrate 110, and the lowest insulating layer 111 may provide a lower surface LS. Depending on the process, the boundary between the plurality of insulating layers 111 may not be apparent. Depending on an example embodiment, a smaller or larger number of insulating layers 111 may be formed than those illustrated in the drawing. When the substrate 110 is a printed circuit board, a core layer located in the middle of the plurality of insulating layers 111 may be thicker than the insulating layers 111 stacked thereabove or therebelow. The core layer may be formed using, for example, a copper clad laminate (CCL), an unclad copper clad laminate (unclad CCL), a glass substrate, or a ceramic substrate. However, the present inventive concepts are not limited thereto, and the substrate 110 may be a printed circuit board not including a core layer.

The interconnection layer 112 may include, for example, a metal material including copper (Cu), aluminum (Al), silver (Ag), tin (Sn), gold (Au), nickel (Ni), lead (Pb), titanium (Ti), or alloys thereof. The interconnection layer 112 may include, for example, a ground (GND) pattern, a power (PoWeR: PWR) pattern, and a signal (Signal: S) pattern. The signal (S) pattern may provide a path for transmitting/receiving various signals, such as data signals, excluding the ground (GND) pattern and the power (PWR) pattern.

The interconnection layer 112 may be provided as a plurality of interconnection layers 112 arranged on the plurality of insulating layers 111, respectively. The plurality of interconnection layers 112 may be electrically connected to each other through interconnection vias 113. The number of the interconnection layers 112 may be determined according to the number of the insulating layers 111 and may include more or fewer layers than those illustrated in the drawing. The interconnection layers 112 located at the lowermost and uppermost positions among the plurality of interconnection layers 112 may include pads 112P on which the semiconductor chip 120 and the connection bumps 140 are mounted. The pads 112P may be formed to have different sizes and/or pitches depending on a target mounted thereon. For example, pads 112P disposed on the lower surface LS of the interconnection layer 112 may have a larger size and/or pitch than those of the pads 112P disposed on the upper surface US.

The interconnection via 113 is electrically connected to the interconnection layer 112 and may include a signal via, a ground via, and a power via. The interconnection via 113 may include a metal material including, for example, copper (Cu), aluminum (Al), silver (Ag), tin (Sn), gold (Au), nickel (Ni), lead (Pb), titanium (Ti), or alloys thereof. The interconnection via 113 may have a filled via formed by filling the inside of a via hole with a metal material or a conformal via in which a metal material is formed along an inner wall of the via hole. The interconnection via 113 may form an integral body with the interconnection layer 112, but example embodiments of the present inventive concepts are not limited thereto.

The upper protective layer 115 may be disposed on the upper surface US of the substrate 110 to cover at least a portion of the interconnection layer 112 and may have first openings exposing at least a portion of the interconnection layer 112. The upper protective layer 115 may be a solder resist layer protecting the interconnection layer 112 from external physical/chemical damage. The solder resist layer may include an insulating material and may be formed using, for example, prepreg, ABF, FR-4, BT, or photo solder resist (PSR).

The semiconductor chip 120 may be disposed on the upper protective layer 115 and may include connection pads 121 electrically connected to the interconnection layer 112. The semiconductor chip 120 may be disposed on the upper protective layer 115 on the inner side of the substrate 110 than the guard structure 200 and may be electrically connected to the interconnection layer 112 through openings in the upper protective layer 115. The semiconductor chip 120 may include silicon (Si), germanium (Ge), or gallium arsenide (GaAs), and various types of integrated circuits may be formed. The integrated circuit may be a processor chip, such as a central processor (e.g., CPU), a graphics processor (e.g., GPU), a field programmable gate array (FPGA), an application processor (AP), a digital signal processor, an encryption processor, a microprocessor, a microcontroller, etc., but is not limited thereto, and may also be a logic chip, such as an analog-to-digital converter or an application-specific IC (ASIC), or a memory chip, such as a volatile memory (e.g., DRAM), a non-volatile memory (e.g., ROM and flash memory). The connection pad 121 may be a pad of a bare chip (e.g., an aluminum (Al) pad), but may also be a pad of a packaged chip (e.g., a copper (Cu) pad) according to an example embodiment.

The semiconductor chip 120 may be mounted on the substrate 110 in a flip-chip manner. For example, in the present example embodiment, the semiconductor chip 120 may have a front surface facing the upper surface US of the upper protective layer 115 and having connection pads 121 arranged thereon and a rear surface located opposite to the front surface. The connection pads 121 may be connected to the interconnection layer 112 via conductive bumps CB. The conductive bumps CB may include, for example, solder, but may include both a pillar and solder according to an example embodiment. The pillar may have a polygonal pillar shape, such as a cylinder, a square pillar, or an octagonal pillar and may include, for example, nickel (Ni), copper (Cu), palladium (Pd), platinum (Pt), gold (Au), or combinations thereof. The solder has a spherical or ball shape and may include, for example, tin (Sn), indium (In), bismuth (Bi), antimony (Sb), copper (Cu), silver (Ag), zinc (Zn), lead (Pb), and/or alloys thereof (e.g., Sn—Ag—Cu).

In the present example embodiment, an underfill portion UF may be disposed below the semiconductor chip 120. The underfill portion UF may have a capillary underfill (CUF) structure, but is not limited thereto. According to an example embodiment, the underfill portion UF may have a molded underfill (MUF) structure formed integrally with the encapsulant 130.

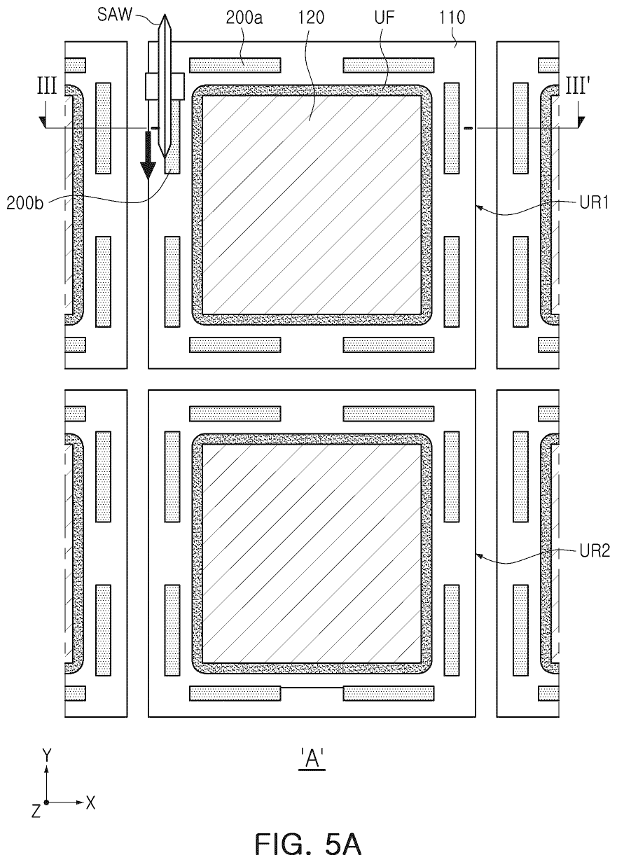

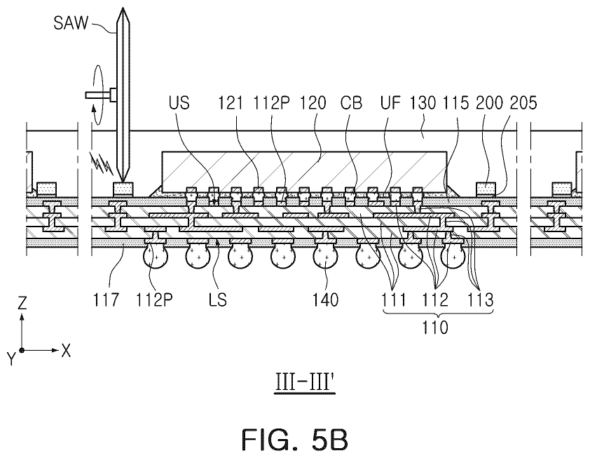

The guard structure 200 may be arranged on the upper protective layer 115 so as to be adjacent to at least a portion of the edge of the semiconductor chip 120. The guard structure 200 may be attached to the upper surface of the substrate 110 or the upper surface of the upper protective layer 115 through an adhesive layer 205. The guard structure 200 may be disposed adjacent to the semiconductor chip 120 on the upper surface US of the substrate 110. A second distance d2 from the guard structure 200 to the adjacent side surface of the semiconductor chip 120 may be greater than, but is not limited to, a first distance d1 from the guard structure 200 to the adjacent outer surface of the substrate 110. The first distance d1 may be, for example, about 10 μm, about 50 μm or more, or about 30 μm to 50 μm, but is not limited thereto. The guard structure 200 may be disposed outside a region defined by the semiconductor chip 120, thereby reducing or preventing the semiconductor chip 120 from being damaged during a cutting process in the manufacturing process of the semiconductor package 100A. The effect of the guard structure 200 in reducing or preventing damage to the semiconductor chip 120 is described below in the description with reference to FIGS. 5A and 5B. A thickness of the guard structure 200 may be smaller than a thickness of the semiconductor chip 120, and the upper surface of the guard structure 200 may be located on a level lower than that of the upper surfaces of each of the semiconductor chip 120 and the encapsulant 130.

The guard structure 200 may be disposed adjacent to each side surface of the semiconductor chip 120 and may be disposed parallel to each side surface. The guard structure 200 may include a first guard structure 200a extending in a first direction (e.g., an X-axis direction) and a second guard structure 200b extending in a second direction (e.g., a Y-axis direction). At least one guard structure 200 may be disposed adjacent to each of the four side surfaces of the semiconductor chip 120.

The enlarged view illustrated in FIG. 1A may be understood as an enlarged view of an interface region of the guard structure 200 and the encapsulant 130. The guard structure 200 may include an insulating resin in which a carbon (C) series filler FL2 is dispersed. The carbon series filler included in the guard structure 200 may be referred to as a second filler FL2. The second filler FL2 may appear in a polyhedral shape with sharp angles. The second filler FL2 may be, for example, a nano-diamond filler, but is not limited thereto. The second filler FL2 may have a hardness range of about 10 or more, or about 9.5 to 10.5, but is not limited thereto.

The lower protective layer 117 may be disposed on the lower surface LS of the substrate 110 and may have second openings exposing at least a portion of the interconnection layer 112. The lower protective layer 117 may be a solder resist layer protecting the lowermost interconnection layer 112 from external physical/chemical damage, corresponding to the first upper protective layer 115. The lower protective layer 117 may include an insulating material similar to that of the first upper protective layer 115.

The encapsulant 130 may encapsulate at least a portion of each of the semiconductor chip 120 and the guard structure 200 on the upper protective layer 115. The encapsulant 130 may include, for example, a thermosetting resin, such as an epoxy resin, a thermoplastic resin, such as a polyimide, or a prepreg, ABF, FR-4, BT, epoxy molding compound (EMC) including an inorganic filler and/or glass fiber. The encapsulant 130 may include an insulating resin in which a silicon (Si)-based filler FL1 is dispersed. The silicon-based filler included in the encapsulant 130 may be referred to as a first filler FL1. The first filler FL1 may have a round, spherical shape. The first filler FL1 may be, for example, a silica (SiO₂) filler, but is not limited thereto. The first filler FL1 may have a lower hardness range than the second filler FL2. An average diameter of the first filler FL1 may be smaller than an average diameter of the second filler FL2, but is not limited thereto.

The connection bumps 140 may be arranged on the lower surface LS of the substrate 110 and may be electrically connected to the interconnection layer 112. The connection bumps 140 may be arranged in openings of the lower protective layer 117, respectively. The connection bumps 140 may physically and/or electrically connect the semiconductor package 100A to an external device. The connection bumps 140 may include a conductive material and may have a ball, pin, or lead shape. For example, the connection bumps 140 may be solder balls.

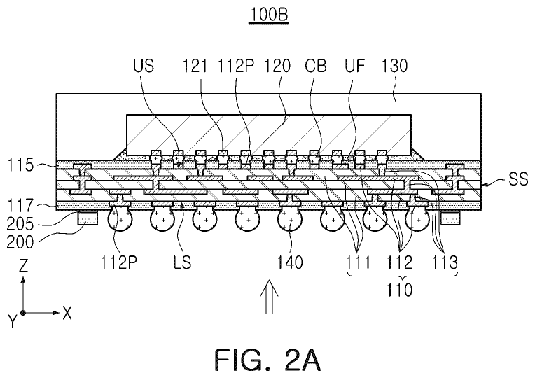

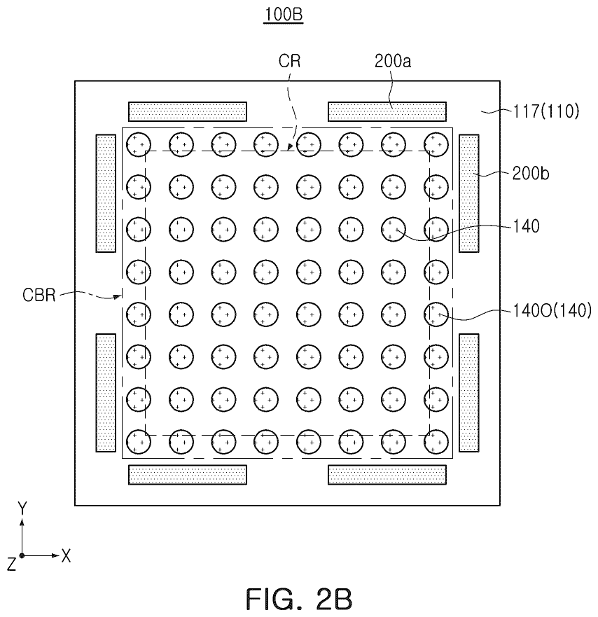

FIG. 2A is a cross-sectional view illustrating a semiconductor package 100B according to an example embodiment of the present inventive concepts, and FIG. 2B is a bottom view of the semiconductor package 100B of FIG. 2A.

Referring to FIGS. 2A and 2B, the semiconductor package 100B of an example embodiment may have the same or similar features as those described above with reference to FIGS. 1A and 1B, except that the guard structure 200 is disposed on the lower surface of the substrate 110. The guard structure 200 may be disposed on the lower surface of the lower protective layer 117 disposed below the substrate 110 and may be attached to the lower protective layer 117 through an adhesive layer 205. The connection bumps 140 may be disposed on the lower surface of the substrate 110, and a region defined by the outermost connection bumps 140O among the connection bumps 140 may be referred to as a bump region CBR. The guard structure 200 may be disposed along at least a portion of the perimeter of the bump region CBR and may be disposed outside the bump region CBR. A height of the guard structure 200 may be smaller than a height of each of the connection bumps 140, but is not limited thereto. The guard structure 200 may be disposed outside the bump region CBR, thereby reducing or preventing a saw blade from cutting the inside of the bump region CBR during a cutting process for manufacturing the semiconductor package.

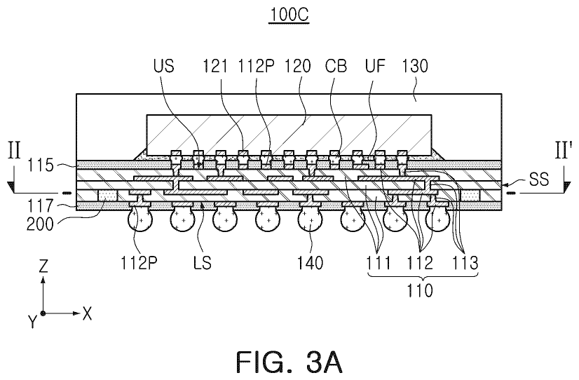

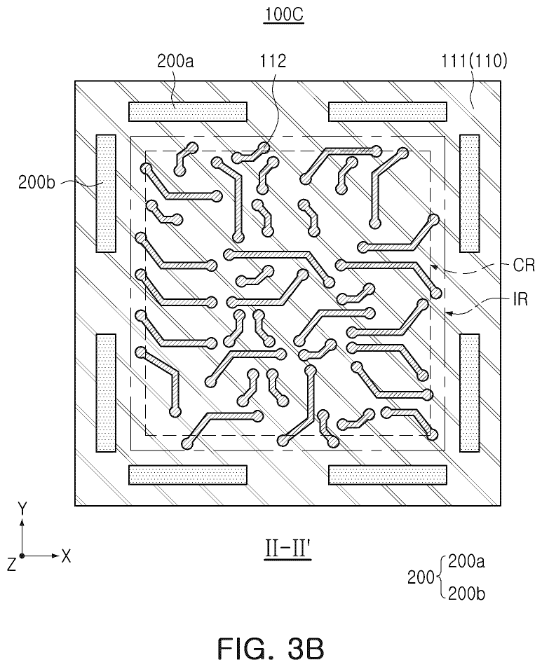

FIG. 3A is a cross-sectional view illustrating a semiconductor package according to an example embodiment of the present inventive concepts, and FIG. 3B is a plan view illustrating a cross-section taken along line II-II′ of FIG. 3A.

Referring to FIGS. 3A and 3B, a semiconductor package 100C of an example embodiment may have the same or similar features as those described above with reference to FIGS. 1A to 2B, except that the guard structure 200 is disposed within the insulating layer 111 of the substrate 110. The guard structure 200 may be disposed within the insulating layer 111 of the substrate 110 and may be spaced apart from the interconnection layer 112 of the substrate 110. A region of the substrate 110 in which the interconnection layer 112 is disposed may be defined as an interconnection region IR, and the guard structure 200 may be disposed along an outer perimeter of the interconnection region IR within the insulating layer 111. The guard structure 200 may be disposed in a partial outer region in which the interconnection layer 112 is not disposed in the operation of forming the substrate 110, and the substrate 110 may be provided in a form having the guard structure 200 therein. In the semiconductor package 100C of the present example embodiment, by disposing the guard structure 200 inside the substrate 110, even when the size of the substrate 110 is similar to the size of each of the semiconductor chip (120, see FIG. 1B) or the bump region (CBR, see FIG. 2B), no space is needed to dispose the guard structure 200 on the upper or lower surface of the substrate 110.

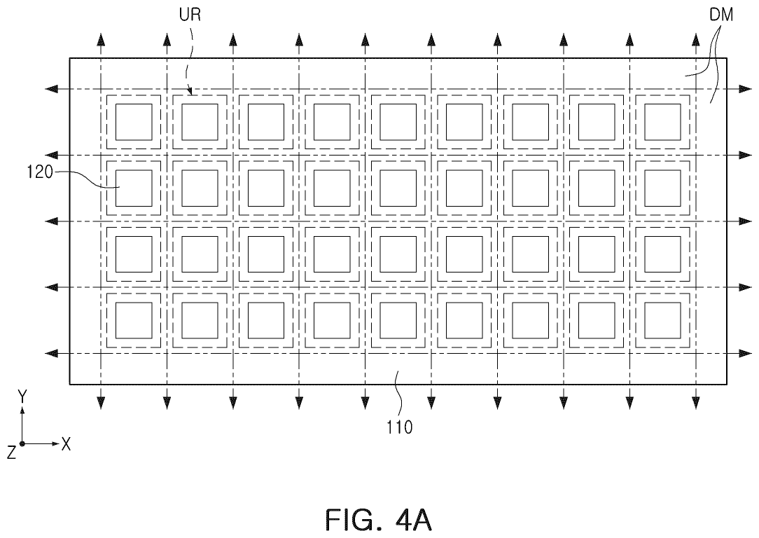

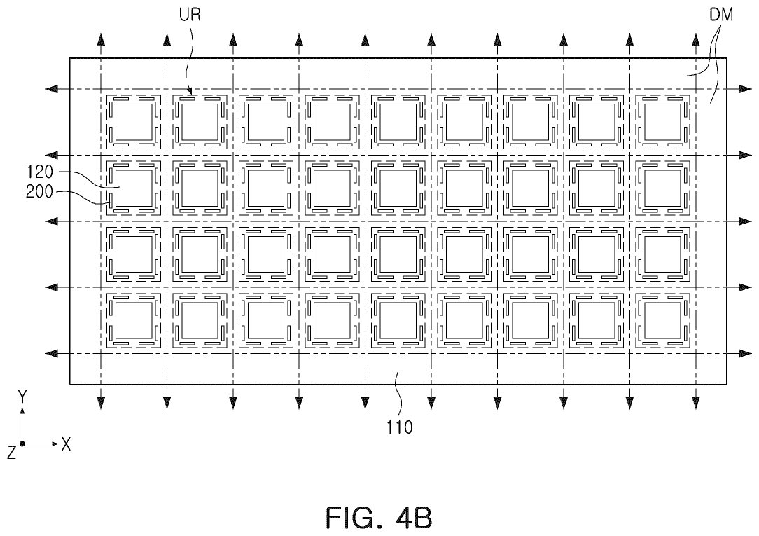

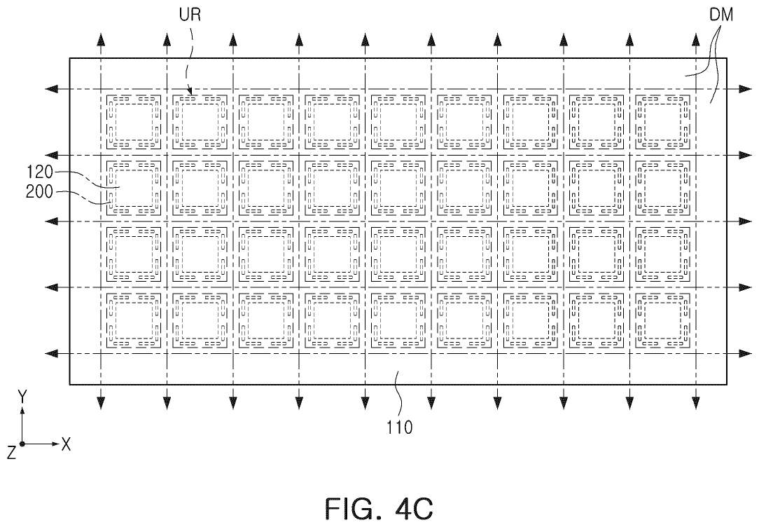

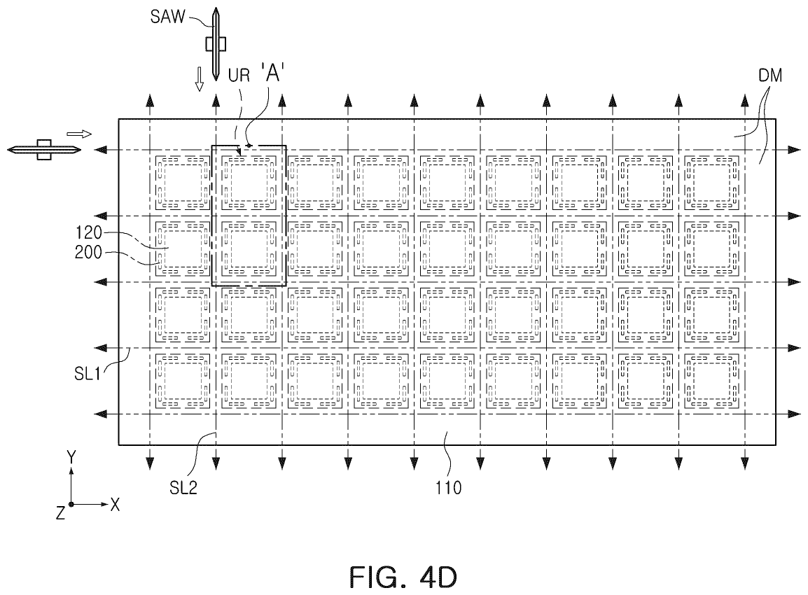

FIGS. 4A to 4D are plan views schematically illustrating a process of manufacturing a semiconductor package according to an example embodiment of the present inventive concepts.

Referring to FIG. 4A, the semiconductor chip 120 may be mounted on each of the plurality of unit regions UR of the substrate 110.

The substrate 110 may be a rectangular plate shape extending in the first direction (e.g., the X-direction) and the second direction (e.g., the Y-direction). The first direction (e.g., the X-direction) may be a direction intersecting the second direction (e.g., the Y-direction). For example, the substrate 110 may be rectangular when viewed from the top.

The package substrate 110 may include a plurality of unit regions UR and a dummy region DM. The dummy region DM may surround the plurality of unit regions UR. The dummy region DM may extend along the edge of the substrate 110. The dummy region DM may have a square ring shape when viewed from the top. Each of the plurality of unit regions UR is a region in which the semiconductor chip 120 is disposed and may be understood as a region corresponding to the semiconductor packages 100A, 100B, and 100C described above with reference to FIGS. 1A to 3B. The unit region UR may have a rectangular shape when viewed from the top. A region between the plurality of unit regions UR may be a region in which an encapsulant (130, see FIG. 4C) is disposed in a subsequent process. The encapsulant may be disposed in at least a portion of the dummy region DM, but is not limited thereto, and according to an example embodiment, the encapsulant 130 may cover the plurality of unit regions UR. The plurality of unit regions UR may be aligned in the second direction (e.g., the Y direction), and the unit regions UR aligned in the second direction may be positioned adjacent to each other. The unit regions UR aligned in the second direction may form a row. The unit regions CR may be aligned in the first direction (e.g., the X direction), and the unit regions UR aligned in the first direction may be positioned adjacent to each other. The unit regions UR aligned in the first direction may form a column. In the present example embodiment, the plurality of unit regions UR are illustrated as 4 rows and 12 columns, but the present inventive concepts are not limited thereto, and the number of unit regions UR on the substrate may be greater or fewer. The substrate 110 is a support substrate on which the semiconductor chips 120 are mounted and may correspond to the substrate 110 in FIGS. 1A to 3B.

Each of the semiconductor chips 120 may be mounted on the plurality of unit regions UR of the substrate 110, respectively. Each of the semiconductor chips 120 may be arranged at the center of a corresponding one of the unit regions UR. The area of each of the upper and lower surfaces of the semiconductor chips 120 may be smaller than the area of each of the unit regions UR.

Referring to FIG. 4B, the guard structure 200 may be disposed within each of the plurality of unit regions UR of the substrate 110.

The guard structure 200 may be disposed in parallel with each of the outer surfaces of the semiconductor chip 120 within the plurality of unit regions UR. Within the unit region UR, the semiconductor chip 120 may be disposed in the center, and the guard structure 200 may be disposed on the outer side. The guard structure 200 may be disposed adjacent to the edge of the unit region UR. In the cutting process to be performed thereafter, a saw blade may move to a region adjacent to the edge of the substrate 110 to perform a cutting process. A horizontal distance from each of the guard structures 200 to the edge of the unit region UR may be about 50 μm or less, about 30 μm to 50 μm, but is not limited thereto.

According to another example embodiment of the semiconductor package 100C, the guard structure 200 may be embedded in the insulating layer 111 of the substrate 110 during a process of preparing the substrate 110 (S10, see FIG. 2B), and a process of disposing the guard structure 200 on the upper or lower surface of the substrate 110 may be omitted. According to another example embodiment of the semiconductor package 100B, the guard structure 200 may be attached to the lower surface of the substrate 110.

Referring to FIG. 4C, the encapsulant 130 (not illustrated in FIG. 4C) may be formed on the upper surface of the substrate 110, and the connection bumps 140 may be formed on the lower surface of the substrate 110.

The encapsulant 130 may be formed to cover a plurality of unit regions UR of the substrate 110. The encapsulant 130 may be formed to cover the entire substrate 110, but is not limited thereto. According to an example embodiment, the encapsulant 130 may not be formed in the dummy region DM of the substrate 110. According to another example embodiment, the encapsulant 130 may be formed partially on the dummy region DM of the substrate 110. The encapsulant 130 may be formed to cover each of the substrate 110, the semiconductor chips 120, and the guard structure 200. The encapsulant 130 may fill the space between the semiconductor chips 120. The encapsulant 130 may be, for example, an epoxy molding compound (EMC).

Referring to FIG. 4D, the substrate 110 and the encapsulant 130 may be cut into a plurality of semiconductor packages 100A using a saw blade (SAW). The operation of cutting into the plurality of semiconductor packages 100A may be performed along a region between the unit regions UR of the substrate 110 and may be understood as an individualization process of the semiconductor package 100A. The region between the unit regions UR may be referred to as a scribe lane. The individualized semiconductor packages 100A may include the substrate 110 cut along a boundary of the unit regions UR, the semiconductor chip 120 disposed thereon, and the encapsulant 130 cut along the boundary of the unit regions UR. The dummy region DM of the substrate 110 may not be included in the individualized semiconductor package 100A and removed.

FIG. 5A is a partial enlarged view illustrating region ‘A’ of FIG. 4D, and FIG. 5B is a cross-sectional view illustrating a cut surface taken along the line III-III′ of FIG. 5A. FIGS. 5A and 5B may be understood as schematic drawings illustrating the effect exerted by disposing the guard structure 200 in the semiconductor package 100A.

As described above with reference to FIG. 4D, the saw blade (SAW) may perform a process of individualizing a plurality of semiconductor packages 100A by cutting the substrate 110 and the encapsulant 130 along the scribe lanes SL defined between the plurality of unit regions UR. However, as can be seen in FIGS. 5A and 5B, if the saw blade (SAW) is not aligned with the scribe lanes SL and intrudes into the unit region UR during the cutting process, the interconnection and/or connection bumps 140 of the substrate may also be subject to the cutting process, which may cause a problem in the reliability of the entire semiconductor package. In the semiconductor package 100A of the present example embodiment, by disposing the guard structure 200 adjacent to the saw blade (SAW), if the saw blade (SAW) comes into contact with the guard structure 200, rather than the scribe lane SL, an overcurrent may occur and the operation of the saw blade (SAW) may be halted. Overcurrent generally refers to a value greater than the current measured when the saw blade (SAW) performs a cutting process along the scribe lane SL, and at this time, the range of the overcurrent at which the operation of the device is halted may be, for example, about 8A or more, but is not limited thereto, and the range may differ depending on the device or equipment. Referring to FIG. 5A, when the saw blade (SAW) comes into contact with the second guard structure 200b in the first unit region UR1, an overcurrent may occur and the operation of the saw blade (SAW) may be halted, thereby reducing or preventing the saw blade (SAW) from progressing into a second unit region UR2 which is aligned parallel to a first unit region UR1 in the second direction (e.g., the Y-axis direction), thereby improving the reliability problem of the semiconductor package. In the subsequent process, the saw blade (SAW) may be aligned again along the scribe lane SL and then resume the cutting and individualization process.

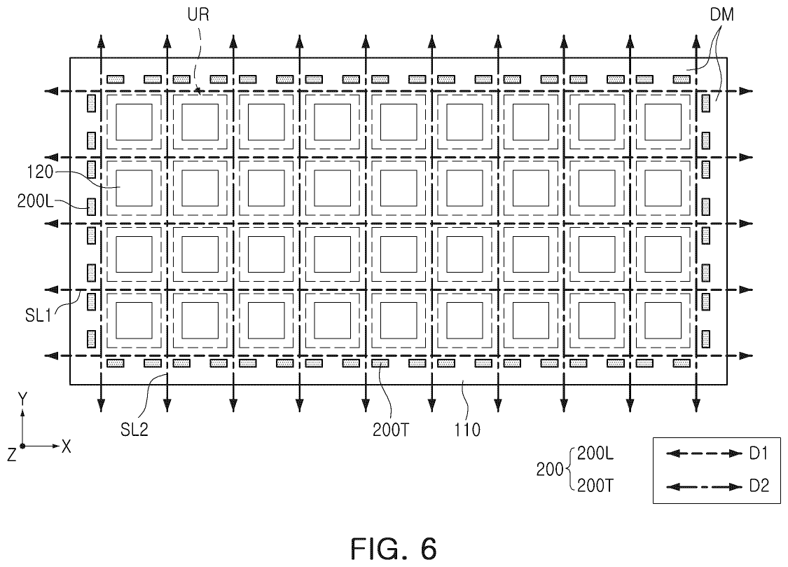

FIG. 6 is a plan view schematically illustrating one operation stage during the manufacturing process of a semiconductor package according to an example embodiment of the present inventive concepts.

FIG. 6 is a plan view illustrating a semiconductor package according to an example embodiment. FIG. 6 may correspond to FIG. 4D in the individualization process of a semiconductor package.

In FIG. 6, the external guard structure 200 may be disposed only in the dummy region DM of the substrate 110. The plurality of unit regions UR may be divided by first scribe lanes SL1 extending in a first direction D1 and second scribe lanes SL2 extending in a second direction D2, intersecting the first direction D1. The external guard structure 200 may include first external guard structures 200L arranged adjacent to both sides of each of the first scribe lanes SL1 and second external guard structures 200T arranged adjacent to both sides of each of the second scribe lanes SL2. The first external guard structures 200L may be understood as guard structures for longitudinal cutting, and the second external guard structures 200T may be understood as guard structures for transverse cutting. The saw blade (SAW) may perform a cutting process, while moving between the first external guard structures 200L aligned in the second direction D2 and between the second external guard structures 200T aligned in the first direction D1 and may perform the cutting process without contacting the first and second external guard structures 200L and 200T). According to an example embodiment, the semiconductor packages 100A, 100B, and 100C of the example embodiments described above may be applied within the plurality of unit regions UR, and accordingly, internal guard structures may be additionally arranged within the plurality of unit regions UR.

According to the above example embodiments of the present inventive concepts, by introducing the guard structure disposed outside from the center than the semiconductor chip and the connection bumps, the semiconductor package with improved reliability may be provided.

While some example embodiments have been shown and described above, it will be apparent to those skilled in the art that modifications and variations could be made without departing from the scope of the present inventive concepts as defined by the appended claims.

What is claimed is:

1. A semiconductor package comprising:
a substrate having a lower surface and an upper surface facing the lower surface, the substrate including an insulating layer and an interconnection layer on the insulating layer;
a semiconductor chip electrically connected to the interconnection layer on the upper surface of the substrate and defining a chip region;
a guard structure on at least one of the upper surface or the lower surface of the substrate and being horizontally outside the chip region;
an encapsulant encapsulating at least a portion of the semiconductor chip on the upper surface of the substrate; and
connection bumps on the lower surface of the substrate and electrically connected to the interconnection layer,
wherein the encapsulant includes a first filler having a spherical shape, and the guard structure includes a second filler having a polyhedral shape.

2. The semiconductor package of claim 1, wherein the first filler includes a silicon (Si) series, and the second filler includes a carbon (C) series.

3. The semiconductor package of claim 2, wherein the second filler is a nano-diamond filler.

4. The semiconductor package of claim 1, wherein an average diameter of the second filler is larger than an average diameter of the first filler.

5. The semiconductor package of claim 1, wherein the second filler has a hardness range of about 9.5 to 10.5.

6. The semiconductor package of claim 1, wherein the guard structure is on the upper surface of the substrate, and a height of the guard structure is smaller than a height of the semiconductor chip.

7. The semiconductor package of claim 1, further comprising:
bump structures electrically connecting the interconnection layer and the semiconductor chip; and
an underfill portion covering at least a portion of each of the bump structures below the semiconductor chip.

8. The semiconductor package of claim 7, wherein the guard structure is on the upper surface of the substrate, and the underfill portion is horizontally spaced apart from an internal surface of the guard structure.

9. The semiconductor package of claim 1, wherein the guard structure is on the lower surface of the substrate and is outside a bump region defined by outermost connection bumps among the connection bumps.

10. The semiconductor package of claim 1, wherein the guard structure is on the lower surface of the substrate, and a height of the guard structure is smaller than a height of each of the connection bumps.

11. The semiconductor package of claim 1, further comprising:
an adhesive layer attaching the guard structure to the upper surface or the lower surface of the substrate.

12. A semiconductor package comprising:
a substrate including an insulating layer and an interconnection layer on the insulating layer;
a semiconductor chip on the substrate and having conductive bumps electrically connected to the interconnection layer;
an underfill portion encapsulating at least a portion of the conductive bumps below the semiconductor chip;
guard structures around the semiconductor chip;
an encapsulant encapsulating at least a portion of the semiconductor chip on the substrate; and
connection bumps below the substrate and electrically connected to the interconnection layer,
wherein the guard structures are arranged outside the connection bumps and are spaced apart from both an edge of the substrate and the underfill portion.

13. The semiconductor package of claim 12, wherein a horizontal distance from each of the guard structures to the edge of the substrate is about 50 μm or less.

14. The semiconductor package of claim 12, wherein the guard structures are embedded within the insulating layer.

15. A method of manufacturing a semiconductor package, the method comprising:
providing a substrate including a plurality of unit regions and a dummy region surrounding the plurality of unit regions;
arranging semiconductor chips within the plurality of unit regions of the substrate, respectively;
attaching guard structures arranged within at least one of the plurality of unit regions or the dummy region;
forming an encapsulant covering each of the semiconductor chips and the guard structures within the plurality of unit regions of the substrate; and
cutting the substrate and the encapsulant into a plurality of semiconductor packages using a saw blade,
wherein the plurality of unit regions are divided by first scribe lanes extending in a first direction and second scribe lanes extending in a second direction intersecting the first direction, and
the guard structures are arranged adjacent to at least one side of each of the first scribe lanes and the second scribe lanes.

16. The method of claim 15, wherein the guard structures include internal guard structures arranged within the plurality of unit regions of the substrate, and the internal guard structures are arranged along at least a portion of a periphery of the semiconductor chips.

17. The method of claim 16, wherein the cutting includes halting an operation of the saw blade in response to the saw blade contacting at least a portion of the internal guard structures.

18. The method of claim 17, further comprising:
aligning the saw blade to one of the first scribe lanes or the second scribe lanes, after the operation of the saw blade has been halted.

19. The method of claim 15, wherein
the guard structures include external guard structures arranged on the dummy region of the substrate, and the external guard structures include first external guard structures arranged adjacent to both sides of each of the first scribe lanes and second external guard structures arranged adjacent to both sides of each of the second scribe lanes.

20. The method of claim 19, wherein the first external guard structures are aligned in parallel in the second direction, and the second external guard structures are aligned in parallel in the first direction.
